(19) United States
(12) Patent Application Publication
(10) Pub. No.: US 2002/0127863 A1
(43) Pub. Date: Sep. 12, 2002

(54) Method of fabricating recessed locos isolation for semiconductor device

(76) Inventor: Ching Hung Chang, Hsinchu (TW)

Correspondence Address: Chun M. Ng, BLAKELY, SOKOLOFF, TAYLOR & ZAFMAN LLP, 12400 Wilshire Boulevard 7th Floor, Los Angeles, CA, 90025, US

(21) Appl. No.: 09/791,314

(22) Filed: Feb. 22, 2001

(51) Int. Cl. H01L 21/76; H01L 21/302; H01L 21/461

(52) U.S. Cl. 438/692; 438/452; 438/448; 438/443; 438/439

(57) ABSTRACT

A pad layer and a silicon nitride layer are respectively formed on a substrate. The multi-layer is then patterned to define active areas. Next, the substrate is etched to form a recessed portion. A sidewal barrier is formed on the sidewall of the recessed portion. A thermal oxidation process is performed using the silicon nitride layer and the sidewal barrier as a mask to form FOX for suppressing oxygen penetration into the substrate during the oxidation process. Therefore, the conventional bird's beak effect is reduced by the method of the present invention.

### FIELD OF THE INVENTION

The present invention relates to a method of fabricating an isolation for semiconductor devices, and more specifically, to a method for forming recessed LOCOS by using sidewall structure.

### BACKGROUND OF THE INVENTION

In recent years, the development of semiconductor devices in which numerous elements are integrated at a high density on a semiconductor chip has been actively under way. In semiconductor fabrication processes employ resolutions in the submicron range. Therefore, for the formation of devices, there have been proposed various processes suitable for miniaturization of the device. To manufacture electric circuits involves the formation of interconnection between devices. Thus, to fabricate ICs, isolation is typically used to separate the devices.

In the formation of integrated circuits, the manufacture of isolation structures between semiconductor devices for insulating on from other is crucial. In either ULSI or in VLSI, a tiny amount of leakage current can induce significant power dissipation for the entire circuit. Therefore, it is very important to form an effective isolation between semiconductor devices. In addition, with the trend towards higher density integration, effective isolation must be done in a smaller isolation space. This is indeed a complicated and challenging task. Isolation techniques such as local oxide of silicon (LOCOS) and shallow trench isolation (STI) have been developed to isolate devices in integrated circuits. In particular, LOCOS has been a widely used isolation technique.

In the LOCOS approach, a silicon oxide layer and a silicon nitride composition layer are selectively grown on a semiconductor wafer, such as a silicon wafer. The silicon oxide layer provides a cushion for reducing stresses between the silicon wafer and the silicon nitride layer. Active regions of the wafer are covered by the silicon oxide/silicon nitride composition layer. The silicon oxide/silicon nitride composition structure serves as a mask for subsequent processing. Then, field oxide (FOX) isolations are formed on the unmasked regions by thermal oxidation in oxygen. Typically, the FOX is thermally grown by wet oxidation at temperatures around 1000° C. for 2 to 4 hours. When FOX isolations are grown, the active regions remain covered by the silicon oxide/silicon nitride composition layer. This prevents oxidation of the silicon wafer, and the oxide grows where there is no silicon nitride masking.

However, at the edges of the silicon nitride, some oxidant laterally diffuses. Oxide forms under the nitride edges and lifts the nitride edges. This lateral extension of the field oxide into the active region of the wafer is known as “bird's beak.” Please refer to FIG. 1A and FIG. 1B. The drawings show the conventional LOCOS structure. Subsequently, the silicon nitride layer is removed and the silicon oxide is stripped by HF solution. The extended bird's beak penetration effect can limit packing density because increased overlap area is needed for forming contacts at the ends of small devices. Further, reducing the size of conventional LOCOS is limited, due to photolithography itself. This limits the sizes to which devices can be scaled down. A variety of LOCOS-based modifications, such as polybuffered LOCOS, sidewall mask isolation (SWAMI), and sealed-interface local oxidation (SILO), have been developed in attempts to reduce the undesirable encroachment of bird's beak.

However, the aforementioned technology is too complicated for manufacture.

### SUMMARY OF THE INVENTION

The object of the present invention is to provide a method of forming recessed LOCOS by using sidewall structure.

First, a pad layer is formed on a substrate, followed by forming a mask composed by silicon nitride. The multi-layer is then patterned to define active areas. A dielectric layer, preferably silicon oxynitride layer, is then formed on the silicon nitride layer and the surface of the recess portion. Next, the oxynitride layer is etched and a portion of the silicon oxynitride layer remains on the sidewall of the recess portion. Alternatively, the sidewall barrier may be composted by multi-layers consisting of silicon nitride and silicon oxynitride (SiₓN_{y}/SiON) or silicon nitride and silicon dioxide (SiₓN_{y}/SiO₂). A thermal oxidation process is performed using the silicon nitride layer and the oxynitride sidewall structure as a mask to form FOX. The silicon oxynitride layer and the silicon nitride layer suppress oxygen penetration into the substrate during the oxidation process. Therefore, the conventional bird's beak effect is reduced by the method of the present invention.

Alternatively, the silicon substrate may be etched to form a deeper recessed portion after forming the sidewall structure, thereby forming the partial SiON sidewall. Other features are similar to the aforementioned embodiment.

### BRIEF DESCRIPTION OF THE DRAWINGS

The foregoing aspects and many of the attendant advantages of this invention will become more readily appreciated by reference to the following detailed description, when taken in conjunction with the accompanying drawings, wherein:

FIG. 1A is a cross-sectional view of a semiconductor wafer illustrating a recess sturcture in accordance with the present invention.

FIG. 1B is a cross-sectional view of a semiconductor wafer illustrating Fox sturcture after oxidation in accordance with the present invention.

FIG. 2A is a cross-sectional view of a semiconductor wafer illustrating a recess structure with sidewall structure in accordance with the present invention.

FIG. 2B is a cross-sectional view of a semiconductor wafer illustrating Fox structure after oxidation in accordance with the present invention.

FIG. 3A is a cross-sectional view of a semiconductor wafer illustrating a recess structure with partial sidewall structure in accordance with the present invention.

FIG. 3B is a cross-sectional view of a semiconductor wafer illustrating Fox structure after oxidation in accordance with the present invention.

### DETAILED DESCRIPTION OF THE PREFERRED EMBODIMENT

Referring to FIG. 2A, a semiconductor device formed according to the present invention suitably includes a single crystal wafer 2 with a <100> or <111> crystallographic orientation. Other substrate material may be used such as GaAs or the like. In a preferred embodiment, a silicon dioxide layer 4 is formed to a thickness of about 150 to 400 angstroms. However, the silicon dioxide layer 4 is suitably formed using thermal oxidation. The temperature for this process may be about higher than 900 centigrade degrees. Alternatively, the silicon oxide layer 4 can also be formed using a chemical vapor deposition (CVD) process, with a tetraethyl orthosilicate (TEOS) source, at a temperature between about 600 to 800° C. and a pressure between about 0.1 to 10 torr. Further, the silicon oxide layer 4 also acts as a cushion between the silicon substrate 2 and a subsequent silicon nitride layer for reducing stress during subsequent oxidation for forming isolation.

Subsequently, a silicon nitride layer 6 is formed on the silicon dioxide 4 to a thickness of about 500 to 1000 angstroms. Still referring to FIG. 2A, after the silicon nitride layer 6 is formed, a photoresist is patterned on the silicon nitride layer 6 to define active areas. The silicon nitride layer 6 and the oxide 4 are etched using the photoresist as an etching mask. It should be note that the silicon substrate 2 is also etched to a depth about 600 to 1000 angstroms. Thereby, a recess portion 8 is formed in the substrate 2. The silicon nitride layer 6 can be deposited by any suitable process. For example, low pressure chemical vapor deposition (LPCVD), plasma enhanced chemical vapor deposition (PECVD), or high density plasma chemical vapor deposition (HDPCVD) maybe used. In the preferred embodiment, the reaction gases used to form silicon nitride layer 6 are SiH₄, NH₃, N₂, N₂O or SiH₂Cl₂, NH₃, N₂, N₂O. In the preferred embodiment, the silicon nitride layer 6 is etched using CF₄ plasma as the etchant. The photoresist is then removed.

A dielectric layer, preferably silicon oxynitride layer 10, is then formed on the silicon nitride layer 6 and the surface of the recess portion 8 in a furnace at about 400 to 450 centigrade degrees. The reaction gases of the process are SiH₄, N₂O and NH₃. The thickness of the silicon oxynitride layer 10 ranges between about 200 to 300 angstroms. The silicon oxynitride layer 10 acts as a barrier to prevent the oxygen from penetrating into the substrate from the sidewall of the recessed portions during subsequent processing.

Next, the oxynitride layer 10 is etched and a portion of the silicon oxynitride layer 10 remains on the sidewall of the recess portion 8. Alternatively, the sidewall barrier may be composed by multi-layers consisting of silicon nitride and silicon oxynitride (SiₓN_{y}/SiON) or silicon nitride and silicon dioxide (SiₓN_{y}/SiO₂).

Now referring to FIG. 2B, a thermal oxidation process is performed using the silicon nitride layer 6 and the oxynitride sidewall structure 10 as a mask at a temperature between about 1000 to 1100° C. to form isolation 12 in the substrate 2. The silicon oxynitride layer 10 and the silicon nitride layer 6 suppress oxygen penetration into the substrate 2 during the oxidation process. Therefore, the conventional bird's beak effect is reduced by the method of the present invention.

The first silicon nitride layer 6 and the silicon oxynitride layer 10 may be removed using a heated solution of phosphorus acid. Then, the silicon oxide layer 4 is also removed by HF or BOE. Thus, FOX isolation region between devices are formed.

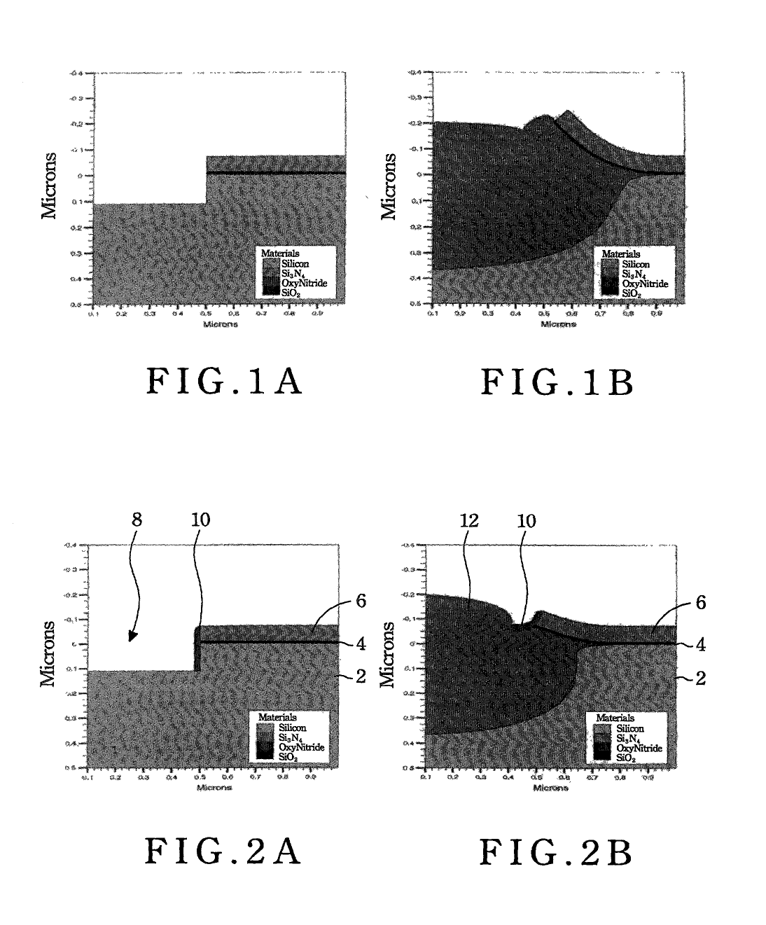

The bird's beak effect can be sufficiently reduced by the method of the present invention. The present invention uses silicon oxynitride and silicon nitride to serve as a buffer structure. From FIG. 1B and FIG. 2B, the length of the bird's beak obtained with the prior art is longer than 0.9 micron meter, as is well known in the art, a long bird's beak and a thick FOX are both unacceptable for scaling down devices. In contrast, in the present invention, the length of the bird's beak is shorter than about 0.7 micron meter.

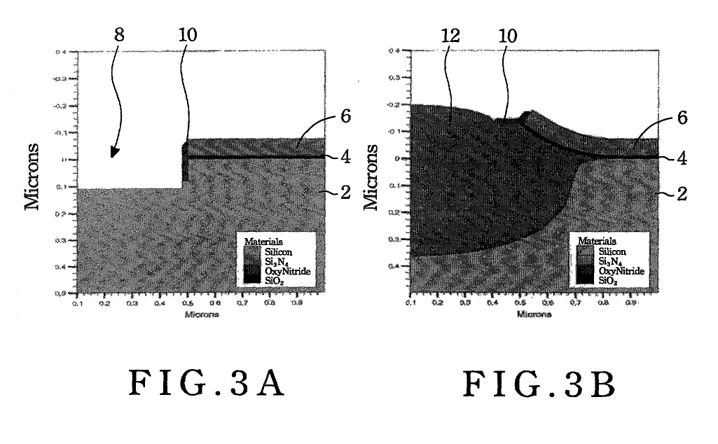

Alternatively, the silicon substrate may be over etched to a depth that is deeper than the previous embodiment. Namely, after the barrier 10 is formed followed by etching the substrate to a depth about 50-150 angstrom. Please refer to FIG. 3A and FIG. 3B. Then, the thermal oxidation is performed to form the FOX. Other features are similar to the aforementioned embodiment, the description is omitted.

As will be understood by a person skilled in the art, the foregoing embodiments illustrate rather than limit the present invention. It is intended that various modifications and similar arrangements are included within the spirit and scope of the appended claims, the scope of which should be accorded the broadest interpretation so as to encompass all such modifications and similar structure. Accordingly, while the preferred embodiment of the invention has been illustrated and described, it will be appreciated that various changes can be made therein without departing from the spirit and scope of the invention.

What is claimed is:

1. A method for forming recess LOCOS with sidewall structure, the method comprising:
forming a pad layer on a substrate;
forming a silicon nitride layer on said pad layer;
patterning said silicon nitride layer and pad layer to expose a portion of the said substrate;
etching said substrate to form a recessed portion in said substrate using said silicon nitride layer as an etching mask;
forming sidewall structure on sidewalls of said recessed portion;
forming an isolation region in said substrate;
wherein said sidewall structure acts as a barrier to block oxygen for reducing bird's beak.

2. The method of claim 1, after forming said isolation region further comprising:
removing said silicon nitride layer; and
removing said pad layer.

3. The method of claim 1, wherein said pad layer comprises a silicon oxide.

4. The method of claim 1, wherein said sidewall structure comprises a silicon oxynitride.

5. The method of claim 1, wherein said sidewall structure comprises silicon nitride and silicon oxynitride (SiₓN_{y}/SiON).

6. The method of claim 1, wherein said sidewall structure comprises silicon nitride and silicon dioxide (SiₓN_{y}/SiO₂).

7. The method of claim 1, wherein said isolation region is formed by thermal oxidation.

8. The method of claim 1, wherein said sidewall structure is formed by following steps:
forming a dielectric layer on said silicon nitride surface and a surface of said recessed portion; and
etching said dielectric layer.

9. A method for forming recess LOCOS with partial sidewall structure, the method comprising:
forming a pad layer on a substrate;
forming a silicon nitride layer on said pad layer;
patterning said silicon nitride layer and pad layer to expose a portion of the said substrate;
etching said substrate to form a recessed portion in said substrate using said silicon nitride layer as etching mask;
forming sidewall structure on sidewalls of said recessed portion;
etching said substrate to form a deeper recessed portion in said substrate using said silicon nitride layer and said sidewall structure as an etching mask;
forming an isolation region in said substrate;
wherein said sidewall structure acts as a barrier to block oxygen for reducing bird's beak.

10. The method of claim 9, after forming said isolation region further comprising:
removing said silicon nitride layer; and
removing said pad layer.

11. The method of claim 9, wherein said pad layer comprises a silicon oxide.

12. The method of claim 9, wherein said sidewall structure comprises a silicon oxynitride.

13. The method of claim 9, wherein said sidewall structure comprises silicon nitride and silicon oxynitride (SiₓN_{y}/SiON).

14. The method of claim 9, wherein said sidewall structure comprises silicon nitride and silicon dioxide (SiₓN_{y}/SiO₂).

15. The method of claim 9, wherein said isolation region is formed by thermal oxidation.

16. The method of claim 9, wherein said sidewall structure is formed by following steps:
forming a dielectric layer on said silicon nitride surface and a surface of said recessed portion; and
etching said dielectric layer.
